(19) United States
(12) Patent Application Publication
(10) Pub. No.: US 2008/0246863 A1
(43) Pub. Date: Oct. 9, 2008

(54) CCD SOLID-STATE IMAGING DEVICE, PHOTOGRAPHIC APPARATUS AND IMAGE DATA CORRECTION METHOD

(76) Inventors: Yoshinori FURUTA, Kurokawa-gun (JP); Hiroyuki Oshima, Kurokawa-gun (JP)

Correspondence Address: BIRCH STEWART KOLASCH & BIRCH, PO BOX 747, FALLS CHURCH, VA, 22040-0747, US

(21) Appl. No.: 12/057,212

(22) Filed: Mar. 27, 2008

(30) Foreign Application Priority Data
Mar. 30, 2007 (JP) P2007-095225

(51) Int. Cl. H04N 5/217

(52) U.S. Cl. 348/250; 348/E05.082

(57) ABSTRACT

A CCD solid-state imaging device is provided and includes: a semiconductor substrate; a plurality of photodiodes arranged in a two-dimensional array; a plurality of vertical charge transfer paths, each reading a signal charge from the photo diodes, wherein electron multiplication of the signal charge is performed in each of the vertical transfer paths; and a storage section that stores data indicating a multiplication factor of the electron multiplication, the multiplication factor being detected at each place of the vertical transfer paths in which the electron multiplication is performed.

This application is based on and claims priority under 35 U.S.C. §119 from Japanese Patent Application No. 2007-95225 filed Mar. 30, 2007, the entire disclosure of which is herein incorporated by reference.

### BACKGROUND OF THE INVENTION

1. Field of the Invention

The present invention relates to a CCD solid-state imaging device, and particularly to a CCD solid-state imaging device for amplifying a signal charge by causing an impact ionization phenomenon in a vertical charge transfer path, a photographic apparatus and an image data correction method.

2. Description of Related Art

In a recent CCD solid-state imaging device, the device becomes finer and a saturation charge amount every pixel becomes small, and when a high-sensitive photograph of a dark scene is taken, a signal charge amount accumulated in each pixel becomes very small. As a result of this, signal amplification is required, but a floating diffusion amplifier (FDA) disposed in an output stage of the CCD solid-state imaging device or its subsequent stage circuit is susceptible to noise and even when the signal amplification is performed in the output stage, an amplification output with high S/N cannot be obtained.

As a result of this, it is preferable to perform the signal amplification in the upstream side of a transfer path of a signal charge rather than the output stage of the CCD solid-state imaging device, and in JP-A-2002-290836, signal amplification is performed in a vertical charge transfer path near to a pixel (photodiode) for generating a signal charge. This signal amplification is performed by using an impact ionization phenomenon.

A charge amount of a signal charge can be amplified by using an impact ionization phenomenon. Furthermore, there is an advantage that amplification can be performed at the time when the amount of dark current mixed during transfer of the signal charge is small since the amplification is performed in the upstream side on a transfer path of the signal charge.

However, the vertical charge transfer paths are disposed every pixel column of multiple pixels formed on a semiconductor substrate surface in a two-dimensional array, so that when signal amplification factors vary every vertical charge transfer path, a difference between the signal amplification factors results in a fixed pattern and image quality of an image signal is reduced. It is very difficult to manufacture a solid-state imaging device so as not to cause this difference, and manufacturing cost of such a solid-state imaging device increases.

### SUMMARY OF THE INVENTION

An object of an illustrative, non-limiting embodiment of the invention is to provide a low-cost CCD solid-state imaging device for suppressing image quality deterioration due to a fixed pattern even when a signal charge amount is amplified in a vertical charge transfer path, a photographic apparatus and an image data correction method.

According to an aspect of the invention, there is provided a CCD solid-state imaging device including: a semiconductor substrate; a plurality of photodiodes arranged in a two-dimensional array; a plurality of vertical charge transfer paths, each reading a signal charge from the photo diodes, wherein electron multiplication of the signal charge is performed in each of the vertical transfer paths; and a storage section that stores data indicating a multiplication factor of the electron multiplication, the multiplication factor being detected at each place of the vertical transfer paths in which the electron multiplication is performed.

According to an aspect of the invention, there is provided a photographic apparatus including: a CCD solid-state imaging device including a semiconductor substrate, a plurality of photodiodes arranged in a two-dimensional array, and a plurality of vertical charge transfer paths, each reading a signal charge from the photo diodes; a driving section that drives the vertical charge transfer paths so that electron multiplication of the signal charge is performed in the each of the vertical charge transfer path; and a storage section that stores data indicating a multiplication factor of the electron multiplication, the multiplication factor being detected at each place of the vertical transfer paths in which the electron multiplication is performed.

The photographic apparatus may further includes an image data correction section that corrects image data output from the CCD solid-state imaging device based on the data stored in the storage section to correct variations in the electron multiplication factor.

In the photographic apparatus, the data indicating the multiplication factor may include a plurality of parameter values dependent on an amount of the signal charge.

In the photographic apparatus, the data indicating the multiplication factor may include data for interpolation among the plurality of parameter values.

In the photographic apparatus, the plurality of parameter values may be values by the number of electron multiplications.

In the photographic apparatus, the plurality of parameter values may be values by voltage value of a pulse voltage for causing the electron multiplication.

In the photographic apparatus, the data stored in the storage section may include: a first multiplication factor different by a threshold value or more from multiplication factors detected around a place in which the first multiplication factor is detected; and a second multiplication factor which is an average value of multiplication factors within the threshold value.

In the photographic apparatus, the multiplication factor may be detected by operating the driving section in a state where a signal charge is not read from the photodiodes to the vertical charge transfer paths so as to perform electron multiplication of a dark current.

The photographic apparatus may further include a light source therein, the light source irradiating the CCD solid-state imaging device with light having an illuminance to accumulate an amount of the signal charge for detecting the multiplication factor in the photodiodes.

The photographic apparatus may further include a multiplication factor correction section that corrects the data stored in the storage section, based on the multiplication factor obtained by operating the driving section in a state where a signal charge is not read from the photodiodes to the vertical charge transfer paths so as to perform electron multiplication of a dark current.

In the photographic apparatus, the multiplication factor correction section may operate the driving section when a working environmental temperature is a degree or higher.

In the photographic apparatus, the data stored in the storage section may be detected when the CCD solid-state imaging device has a temperature of a room temperature or lower.

According to an aspect of the invention, there is provided a method for correcting an image data, the image data obtained by a CCD solid-state imaging device including a semiconductor substrate, a plurality of photodiodes arranged in a two-dimensional array, and a plurality of vertical charge transfer paths, each reading a signal charge from the photo diodes, wherein electron multiplication of the signal charge is performed in each of the vertical transfer paths, the method including correcting image data output from the CCD solid-state imaging device by multiplication factor data to suppress variations in multiplication factor of the electron multiplication with respect to a place in the vertical charge transfer path, wherein the multiplication factor date is acquired in advance.

### BRIEF DESCRIPTION OF THE DRAWINGS

The features of the invention will appear more fully upon consideration of the exemplary embodiments of the inventions, which are schematically set forth in the drawings, in which:

FIG. 1 is a surface schematic diagram of a CCD solid-state imaging device according to an exemplary embodiment of the invention;

FIG. 2 is an explanatory diagram of vertical transfer in the CCD solid-state imaging device;

FIG. 3 is an enlarged surface diagram of a photodiode (PD) shown in FIG. 1;

FIG. 4 is an explanatory diagram of electron multiplication performed in a vertical charge transfer path;

FIG. 5 is a diagram showing variations in an electron multiplication factor at the time of performing electron multiplication in the vertical charge transfer path;

FIG. 6 is a diagram showing variations in electron multiplication factor at the time of increasing the number of electron multiplications performed in the vertical charge transfer path;

FIG. 7 is a graph showing one example of a relation between a multiplication factor and the number of electron multiplications;

FIG. 8 is a diagram illustrating a peculiar value of an electron multiplication factor;

FIG. 9 is a detection explanatory diagram of an electron multiplication factor in which influence of a dark current is eliminated;

FIG. 10 is an explanatory diagram in which a light source for inspection is mounted in a photographic apparatus;

FIG. 11 is a chart showing driving timing of a normal CCD solid-state imaging device;

FIG. 12 is a driving timing chart in the case of lengthening time for which vertical transfer is stopped; and

FIG. 13 is a diagram showing detection timing of an electron multiplication factor by a dark current at the time of 2-field readout.

### DETAILED DESCRIPTION OF THE EXEMPLARY EMBODIMENTS

Although the invention will be described below with reference to the exemplary embodiment thereof, the following exemplary embodiment and its modification do not restrict the invention.

According to an exemplary embodiment of the invention, dependence of an electron multiplication factor on a place can be corrected, so that fixed pattern noise of imaged image data can be suppressed and a high-quality image can be imaged.

An exemplary embodiment of the invention will hereinafter be described with reference to the drawings.

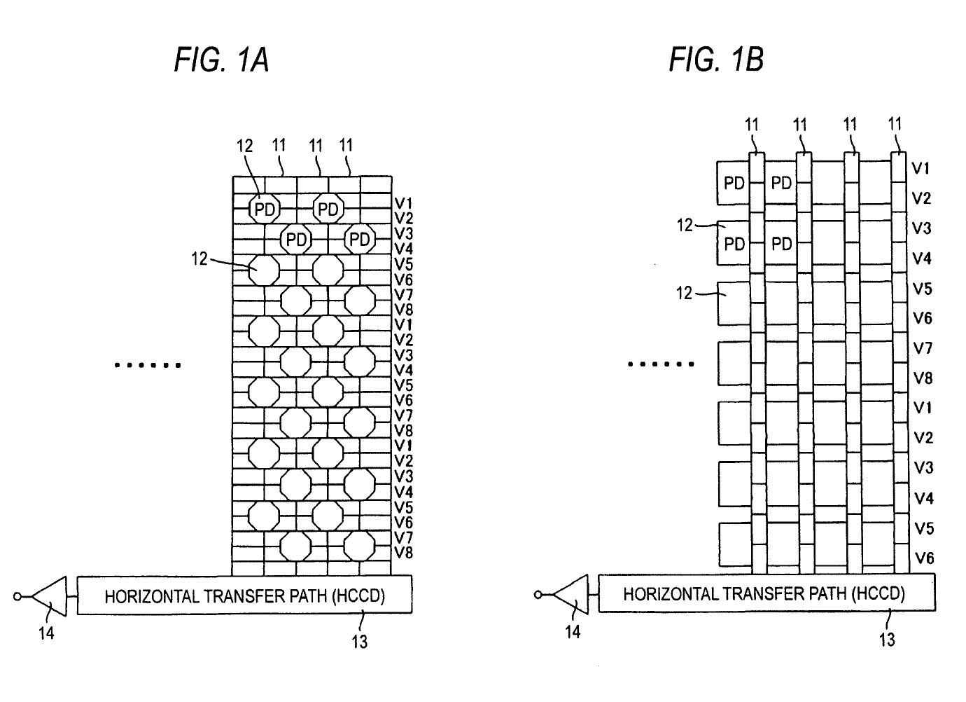

FIG. 1 is a surface schematic diagram of a CCD solid-state imaging device to which an exemplary embodiment of the invention is applied. FIG. 1A is a solid-state imaging device of the so-called honeycomb pixel arrangement in which pixel (photodiode: PD) rows of odd rows are shifted by ½ pitch with respect to pixel rows of even rows. Vertical charge transfer paths 11 extending in a vertical direction along each of the pixel columns are disposed in a meandering state so as to avoid each pixel 12, and a horizontal charge transfer path 13 is disposed along the end of each of the vertical charge transfer paths 11, and an amplifier 14 for converting a signal charge amount into a voltage value signal is disposed in an output stage of its horizontal charge transfer path 13. V1, V2, . . . , V8 show transfer electrode layers, and the same transfer pulse is applied to the transfer electrode layers of the same number.

FIG. 1B shows a solid-state imaging device in which pixels 12 are arranged in a tetragonal lattice, and vertical charge transfer paths 11 extending on a straight line along each of the pixel columns are disposed, and a horizontal charge transfer path 13 is disposed along the end of each of the vertical charge transfer paths 11, and an amplifier 14 for converting a signal charge amount into a voltage value signal is disposed in an output stage of its horizontal charge transfer path 13. In a manner similar to the above, V1, V2, . . . , V8 show transfer electrode layers, and the same transfer pulse is applied to the transfer electrode layers of the same number.

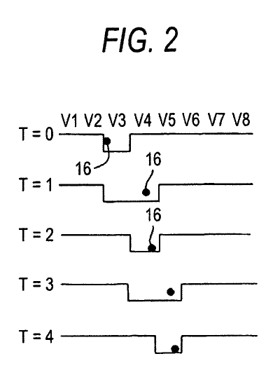

FIG. 2 is a diagram showing a situation of transfer by the vertical charge transfer paths. At time T=0, 0 V is applied to an electrode V3 and a signal charge 16 is held inside a potential well formed in a lower part of the electrode V3. At time T=1, 0 V is also applied to an electrode V4 and the potential well expands to a lower part of the electrode V4 and when −8 V is applied to the electrode V3 at the next T=2, the potential well is present in only the lower part of the electrode V4. Consequently, the signal charge advances by one electrode from the state of T=0. Thus, the signal charge is transferred to the horizontal charge transfer path 13 while expanding and contracting a length of the potential well.

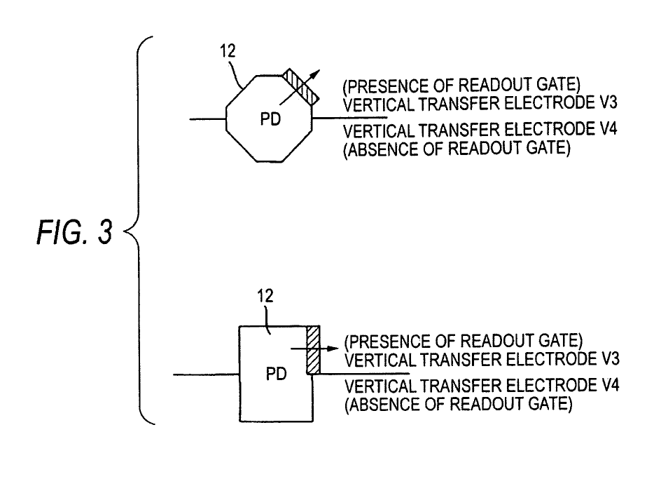

FIGS. 3A and 3B are respectively enlarged diagrams of the photodiodes (pixels) 12 to which the transfer electrode layers V3, V4 shown in FIGS. 1A and 1B are adjacent. The transfer electrode layers V3, V4 are disposed adjacently to each of the pixels 12 and the transfer electrode layer V3 is disposed so as to extend in a direction of the pixel 12, so that a readout electrode is combined. Since the electrode V4 does not combine the readout electrode, a signal charge is not read from the pixel 12 to the potential well of the lower part of the electrode V4 even when a high voltage of about 15 V is applied to the electrode V4.

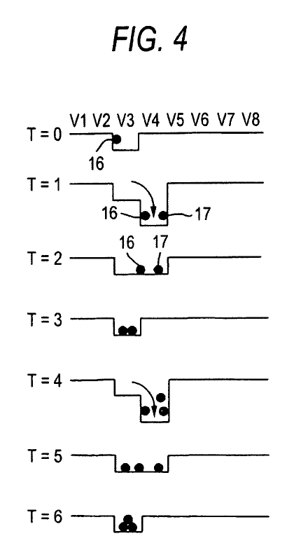

FIG. 4 is a diagram showing a situation in which a signal charge amount is amplified by an impact ionization phenomenon. The signal charge 16 read out the pixel is present inside the potential well formed in the lower part of the transfer electrode V3 combined with the readout electrode at time T=0. In this case, a voltage of 0 V is applied to the electrode V3.

At the next time T=1, a voltage of +15 V is applied to the transfer electrode V4. Consequently, a deep potential well is formed in the lower part of the electrode V4 and the signal charge 16 drops inside this deep potential well. Even in this potential difference (15 V), electron multiplication (or electron amplification) occurs by an avalanche effect (impact ionization phenomenon) and the signal charge 16 multiplies at a certain amplification factor (i.e., multiplication factor). The multiplied signal charges 16, 17 are again held inside a shallow potential well of the lower part of the electrode V3 and are again dropped inside the deep potential well in the lower part of the electrode V4 and thereby, the electron multiplication is caused.

Even when an electron multiplication factor by one impact ionization phenomenon is “1.01”, 100 repeats enable to increase the multiplication factor to 2.7 times.

In the case of manufacturing the CCD solid-state imaging device using a semiconductor integrated circuit manufacturing technique, it is impossible to identically manufacture structures of all the vertical charge transfer paths and the transfer electrodes. Therefore, manufacturing variations occur in a structure of a place in which signal charge multiplication every each pixel is performed and this results in variations in the electron multiplication factor.

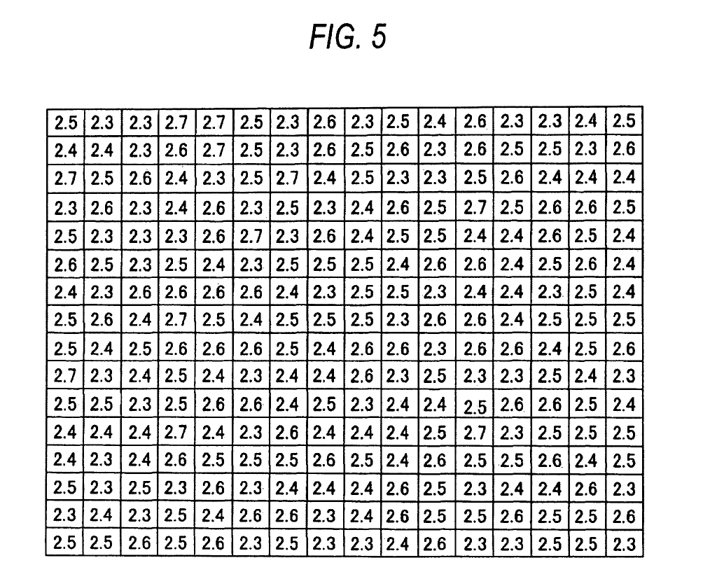

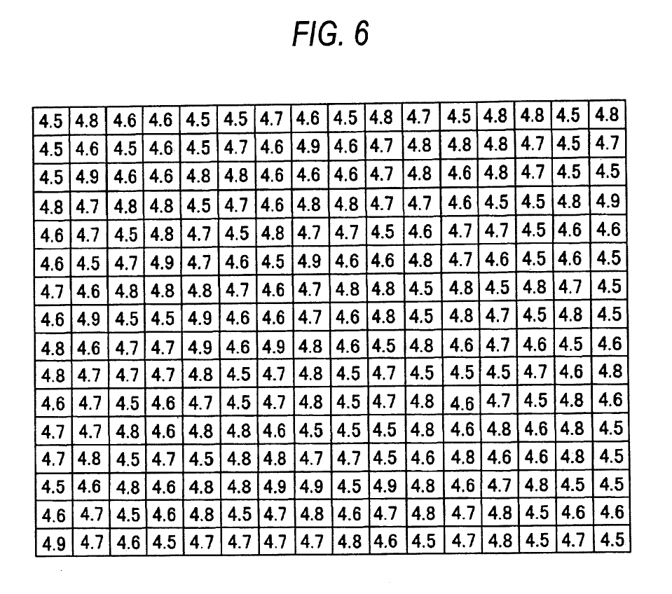

FIG. 5 is a diagram illustrating the electron multiplication factors at places in which signal charge multiplication corresponding to each pixel is performed. By repeating the impact ionization phenomena described in FIG. 4 100 times, multiplication is performed to about 2.7 times, but some variations occur. FIG. 6 is a diagram showing variations in an electron multiplication factor at the time of further increasing the number of times in which an impact ionization phenomenon is caused.

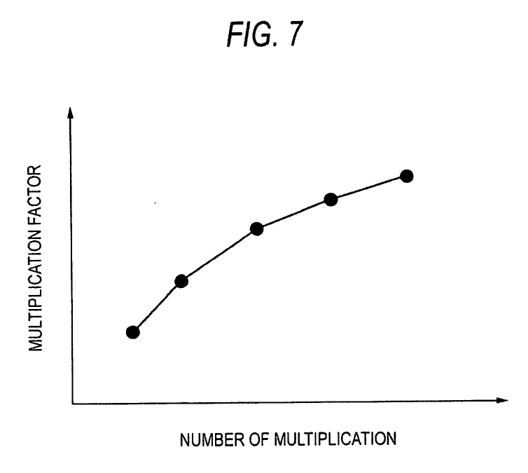

FIG. 7 is a graph illustrating a relation between a multiplication factor of a signal charge and the number of multiplications in which an impact ionization phenomenon is caused. The graph has substantially a linear relation, but may have a nonlinear relation. This could be obtained every solid-state imaging device by inspection.

Hence, fixed pattern noise occurring due to variations in an electron multiplication factor every place can be eliminated by: for example, obtaining a relational expression of FIG. 7, which is obtained from numerical values shown in FIG. 6 in which the number of multiplications is further increased and numerical values shown in FIG. 5 at the time of repeating electron multiplication 100 times every place in which the electron multiplication is performed, by inspection etc. after a CCD solid-state imaging device is manufactured; writing this relationship in memory on a chip in which the CCD solid-state imaging device is formed or storing this relationship in memory of a CPU for controlling a photographic apparatus including the CCD solid-state imaging device; and correcting an output image signal of the CCD solid-state imaging device based on the memory storage data.

FIGS. 5 and 6 show parameter values of multiplication factors every the number of electron multiplications. Since the electron multiplication factor also depends on a voltage for forming a potential well for electron multiplication, that is, a difference (15 V in the above example) between a VL voltage and a VH voltage, a multiplication factor may be had every pulse voltage value for potential multiplication. In addition, using the CCD solid-state imaging device, the maker side for manufacturing a digital camera may independently inspect and store these memory storage data in the memory.

The data of the electron multiplication factors of FIGS. 5 and 6 are only an example of a solid-state imaging device having only 16 by 16 pixels. An actual solid-state imaging device has ten million pixels or more in recent years and when the solid-state imaging device has data of all the electron multiplication places, the amount of data becomes enormous and memory capacity for retaining the data also becomes large and the cost increases.

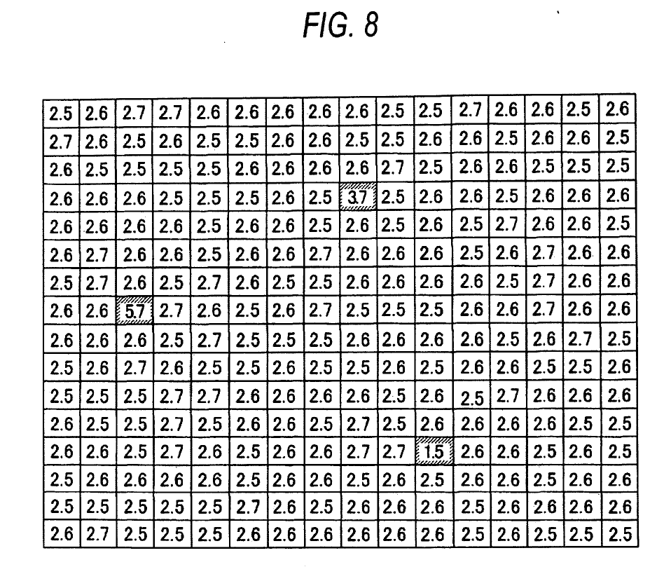

Hence, as shown in FIG. 8, data at places indicating specific numerical values as compared with the periphery are individually stored and as the other data, an average value excluding the specific numerical values is used and thereby, the amount of necessary data can also be reduced. The average value may be all the average values of a region in which electron multiplication is performed, or the region in which electron multiplication is performed is divided into plural regions and an average value every each divided region may be used.

In the case of obtaining an electron multiplication factor, accuracy can be increased when the amount of dark current included in a charge amount targeted for multiplication is small. As a result of this, the electron multiplication factor could be detected at lower temperature so that the amount of dark current becomes small. However, when the temperature is too low, the electron multiplication factor cannot be detected easily, and accordingly, a photographic apparatus could be inspected at a temperature lower than an environmental temperature used usually. In the case of, for example, room temperature or lower (10° C. to 20° C.), the electron multiplication factor with sufficient accuracy can be obtained.

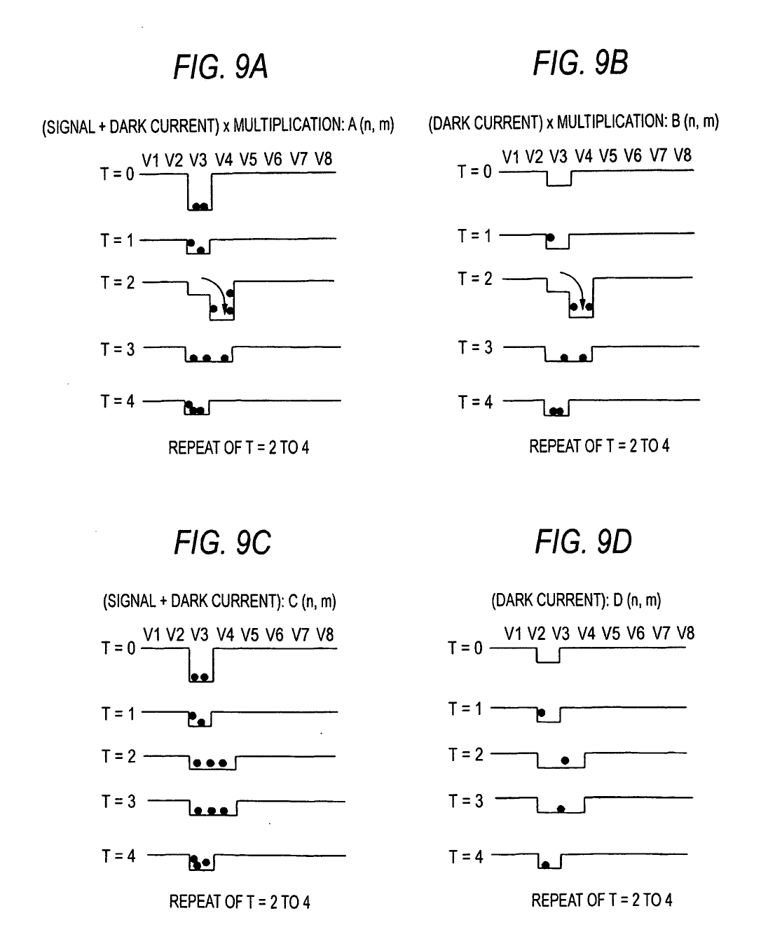

The following method described in FIG. 9 could be adopted in order to calculate an electron multiplication factor K with higher accuracy. When electron multiplication of a signal charge is performed in a vertical charge transfer path, electron multiplication of the amount of dark current is also performed. Hence, the amount of dark current is corrected in the following manner.

In FIG. 9A, a signal charge accumulated by the photodiode 12 is read out inside a potential well of a lower part of an electrode V3 by applying a readout voltage of, for example, +10 V to the transfer electrode V3. Then, as described in FIG. 4, an impact ionization phenomenon is repeated by a specific number of times between the electrodes V3 and V4 and electron multiplication is performed. However, the amount of dark current in which electron multiplication is performed is also included in a charge amount multiplied. When it is assumed that a charge amount after multiplication is A(n, m), this results in a signal charge in which electron multiplication is performed plus a dark current in which electron multiplication is performed. In addition, (n, m) indicates a position of row n and column m of FIG. 5.

In FIG. 9B, a signal from the photodiode is not read out and electron multiplication is repeated by a specific number of times. A charge amount obtained is a charge amount in which electron multiplication of the amount of dark current is performed, and this is set at B(n, m).

In FIG. 9C, an accumulated charge of the photodiode is read out inside the potential well of the lower part of the electrode V3 in a manner similar to FIG. 9A. However, electron multiplication is not performed, and only contraction of length of the potential well is repeated by a specific number of times and a charge amount obtained is set at C(n, m). This charge amount results in a signal charge amount plus the amount of dark current.

In FIG. 9D, a signal charge from the photodiode to the vertical charge transfer path is not read out, and only contraction of length of the potential well of the lower part of the electrode V3 is repeated by a specific number of times. A charge amount obtained is set at D(n, m). This charge amount is the amount of dark current.

An electron multiplication amount of only a signal charge can be obtained by calculating {A(n, m)−B(n, m)}, and a signal charge amount from which the amount of dark current is subtracted can be obtained by calculating {C(n, m)−D(n, m)}.

Hence, an electron multiplication factor of only the signal charge can be obtained by calculating K={A(n, m)−B(n, m)}/{C(n, m)−D(n, m)}.

In the case of obtaining a parameter value of the electron multiplication factor K described above by inspection, it is necessary to prepare a light source capable of uniformly irradiating a CCD solid-state imaging device with light from the light source and accurately adjusting illuminance of this light, that is, a signal charge amount.

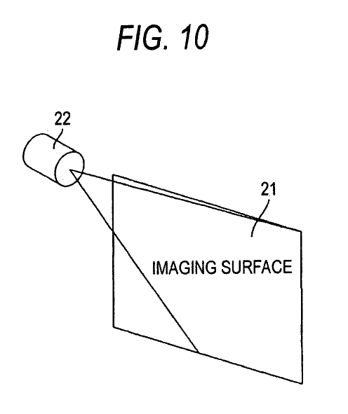

Also, the parameter value of the electron multiplication factor once inspected may vary depending on change of a solid-state imaging device with age. Hence, for example, an LED light source 22 or a flash light source for uniformly illuminating an imaging surface 21 of the solid-state imaging device as shown in FIG. 10 is installed inside a photographic apparatus, and when a photograph is not taken by the photographic apparatus, the imaging surface 21 is illuminated by this light source 22 and a signal charge is accumulated in a photodiode and an impact ionization action or expansion and contraction of the potential well described in FIG. 9 is performed, and thereby, the parameter value of the electron multiplication factor corresponding to the change of the solid-state imaging device with age can be updated.

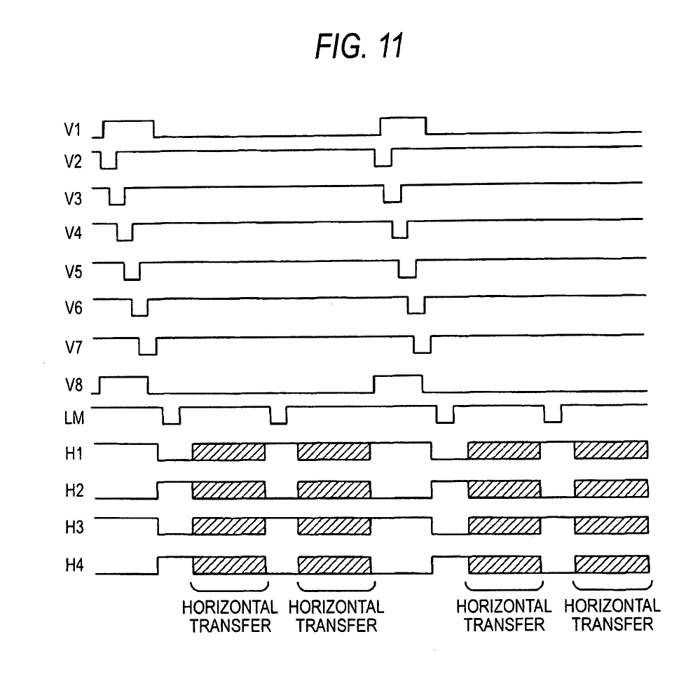

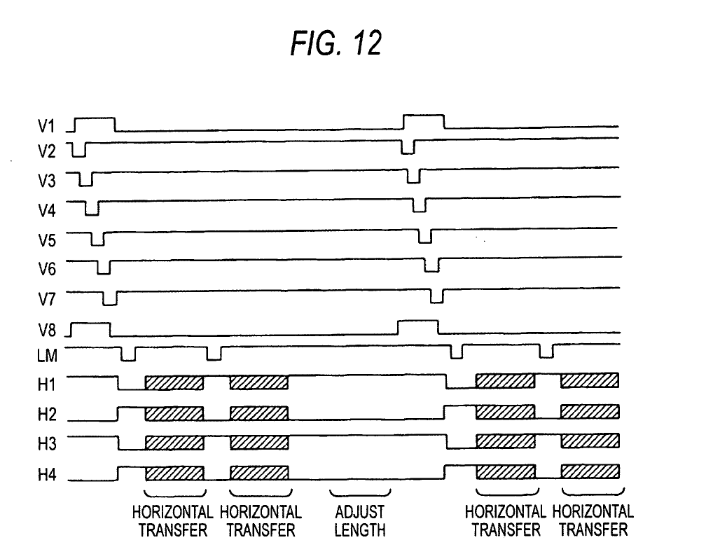

In the embodiment described above, the electron multiplication factor is obtained using the signal charge as a main body, but the electron multiplication factor can also be detected simply by only the amount of dark current. FIG. 11 is a driving timing chart of a normal CCD solid-state imaging device. Also, during the normal driving, the amount of dark current occurs in a vertical charge transfer path and is accumulated. Since the dark current is very small, the amount of dark in the vertical charge transfer path may be increased by lengthening time for which vertical transfer is stopped as shown in FIG. 12.

Then, the electron multiplication factor can be calculated by performing multiplication of the amount of dark current in a driving mode of FIG. 9B and dividing an obtained charge amount by a dark current obtained in the driving mode of FIG. 9D.

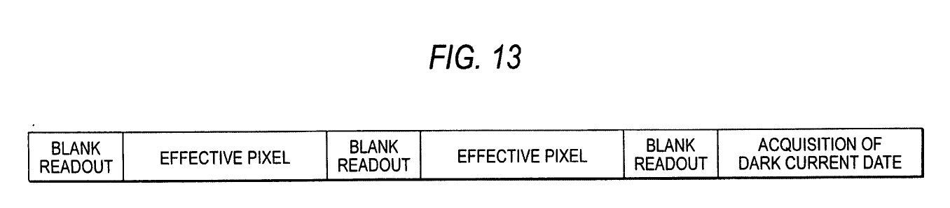

FIG. 13 is a diagram showing driving timing in the case of detecting an electron multiplication factor using a dark current and in this example, 2-field readout is performed from a solid-state imaging device and data of the electron multiplication factor by the dark current is acquired without performing readout of a signal charge from each pixel after the 2-field readout.

Simple detection of the electron multiplication factor obtained from electron multiplication of this amount of dark current can also be implemented after a solid-state imaging device is mounted in a photographic apparatus, and an electron multiplication factor without considering the amount of dark current because of inspection at low temperature retained inside memory and detected previously as shown in FIG. 5 is corrected at the electron multiplication factor obtained from the dark current, and thereby, change of the solid-state imaging device with age can also be corrected.

Or, the electron multiplication factor of FIG. 5 can also be corrected at the electron multiplication factor obtained by the dark current when the need to consider the amount of dark current by a working environmental temperature of a photographic apparatus at that time arises rather than the change with age. Since it is necessary to consider the amount of dark current at the time of a state in which ambient temperature is high and a rate of occurrence of the dark current is high, at the time when a specific temperature or higher is detected by a temperature sensor or when the amount of dark current is larger than or equal to a specific amount, the electron multiplication factor by the dark current shown in FIG. 13 is detected and at the time other than its time, the electron multiplication factor by the dark current is not detected and thereby, photography time could be reduced.

In addition, in the embodiment described above, when the signal charge is read out of the photodiode on the vertical charge transfer path, the impact ionization phenomenon is not caused, but an impact ionization phenomenon may be caused at the time of readout and an impact ionization phenomenon may further be caused on a vertical charge transfer path.

According to an exemplary the invention, it is useful in being applied to a digital camera etc. equipped with a high-sensitive mode having a small signal charge amount since fixed pattern noise is eliminated by a CCD solid-state imaging device etc. for repeating electron multiplication on a vertical charge transfer path and amplifying a signal charge amount.

What is claimed is:

1. A CCD solid-state imaging device comprising:
a semiconductor substrate;
a plurality of photodiodes arranged in a two-dimensional array;
a plurality of vertical charge transfer paths, each reading a signal charge from the photo diodes, wherein electron multiplication of the signal charge is performed in each of the vertical transfer paths; and
a storage section that stores data indicating a multiplication factor of the electron multiplication, the multiplication factor being detected at each place of the vertical transfer paths in which the electron multiplication is performed.

2. A photographic apparatus comprising:
a CCD solid-state imaging device including a semiconductor substrate, a plurality of photodiodes arranged in a two-dimensional array, and a plurality of vertical charge transfer paths, each reading a signal charge from the photo diodes;
a driving section that drives the vertical charge transfer paths so that electron multiplication of the signal charge is performed in the each of the vertical charge transfer path; and
a storage section that stores data indicating a multiplication factor of the electron multiplication, the multiplication factor being detected at each place of the vertical transfer paths in which the electron multiplication is performed.

3. The photographic apparatus according to claim 2, further comprising an image data correction section that corrects image data output from the CCD solid-state imaging device based on the data stored in the storage section to correct variations in the electron multiplication factor.

4. The photographic apparatus according to claim 3, wherein the data indicating the multiplication factor includes a plurality of parameter values dependent on an amount of the signal charge.

5. The photographic apparatus according to claim 4, wherein the data indicating the multiplication factor includes data for interpolation among the plurality of parameter values.

6. The photographic apparatus according to claim 4, wherein the plurality of parameter values are values by the number of electron multiplications.

7. The photographic apparatus according to claim 4, wherein the plurality of parameter values are values by voltage value of a pulse voltage for causing the electron multiplication.

8. The photographic apparatus according to claim 2, wherein the data stored in the storage section includes: a first multiplication factor different by a threshold value or more from multiplication factors detected around a place in which the first multiplication factor is detected; and a second multiplication factor which is an average value of multiplication factors within the threshold value.

9. The photographic apparatus according to claim 2, wherein the multiplication factor is detected by operating the driving section in a state where a signal charge is not read from the photodiodes to the vertical charge transfer paths so as to perform electron multiplication of a dark current.

10. The photographic apparatus according to claim 2, further comprising a light source therein, the light source irradiating the CCD solid-state imaging device with light having an illuminance to accumulate an amount of the signal charge for detecting the multiplication factor in the photodiodes.

11. The photographic apparatus according to claim 2, further comprising a multiplication factor correction section that corrects the data stored in the storage section, based on the multiplication factor obtained by operating the driving section in a state where a signal charge is not read from the photodiodes to the vertical charge transfer paths so as to perform electron multiplication of a dark current.

12. The photographic apparatus according to claim 11, wherein the multiplication factor correction section operates the driving section when a working environmental temperature is a degree or higher.

13. The photographic apparatus according to claim 2, wherein the data stored in the storage section is detected when the CCD solid-state imaging device has a temperature of a room temperature or lower.

14. A method for correcting an image data, the image data obtained by a CCD solid-state imaging device including a semiconductor substrate, a plurality of photodiodes arranged in a two-dimensional array, and a plurality of vertical charge transfer paths, each reading a signal charge from the photo diodes, wherein electron multiplication of the signal charge is performed in each of the vertical transfer paths,
the method comprising correcting image data output from the CCD solid-state imaging device by multiplication factor data to suppress variations in multiplication factor of the electron multiplication with respect to a place in the vertical charge transfer path, wherein the multiplication factor date is acquired in advance.
